(19) United States
(12) Patent Application Publication
(10) Pub. No.: US 2024/0186282 A1
(43) Pub. Date: Jun. 6, 2024

(54) DIE BONDING APPARATUS

(71) Applicant: Samsung Electronics Co., Ltd., Suwon-si (KR)

(72) Inventors: Sumin Kim, Suwon-si (KR); Minwoo Rhee, Suwon-si (KR); Ilyoung Han, Suwon-si (KR); Sujie Kang, Suwon-si (KR); Juno Kim, Suwon-si (KR); Daeho Min, Suwon-si (KR); Kyeongbin Lim, Suwon-si (KR)

(21) Appl. No.: 18/239,454

(22) Filed: Aug. 29, 2023

(30) Foreign Application Priority Data
Dec. 1, 2022 (KR) 10-2022-0165966

(51) Int. Cl. H01L 23/00

(52) U.S. Cl. CPC H01L 24/75; H01L 2224/75252; H01L 2224/75735; H01L 2224/75745; H01L 2224/75804; H01L 2224/75841; H01L 2924/2064

(57) ABSTRACT

A die bonding apparatus comprising a stage configured to support a first die, a pickup head configured to pick up a second die, regions of magnetic materials arranged on the first die and the second die, an electromagnet arranged on a surface of the pickup head or the stage; and a controller configured to apply a current to the electromagnet to generate a magnetic field when the first die and the second die are disposed at a predetermined distance from each other in a vertical direction. As a result of the magnetic field generated by the electromagnet, the regions of magnetic material arranged on first die and the second die are aligned with one another in the vertical direction.

### CROSS-REFERENCE TO RELATED APPLICATION

This application is based on and claims priority under 35 U.S.C. § 119 to Korean Patent Application No. 10-2022-0165966, filed on Dec. 1, 2022, in the Korean Intellectual Property Office, the disclosure of which is incorporated by reference herein in its entirety.

### BACKGROUND

Aspects of the inventive concept relate to a die bonding apparatus, and more particularly, to a die bonding apparatus capable of bonding a plurality of dies in a vertical direction.

Generally, semiconductor devices may be formed on a silicon wafer used as a semiconductor substrate as a series of manufacturing processes are repeatedly performed. The wafer, on which the semiconductor devices are formed, may be individualized into multiple dies through a dicing process, and the dies individualized through the dicing process may be bonded onto a substrate, such as a lead frame, a printed circuit board, or a semiconductor wafer, through a die bonding process.

An apparatus for performing the die bonding process may include a die pickup module for picking up and separating the dies from the wafer, which is divided into the dies, and a die bonding module for attaching the dies onto a substrate. The die pickup module may include a stage unit for supporting the wafer, a die ejector for selectively separating the dies from the wafer supported on the stage unit, and a picker for picking up the dies from the wafer and transferring the dies to the die bonding module. The die bonding module may include a substrate stage for supporting the substrate and a bonding head for vacuum-adsorbing the dies and bonding the dies to the substrate.

Recently, as the integration degree of semiconductor devices increases, pad pitches of the dies have been gradually decreasing. Therefore, the precise alignment of the dies has been highlighted as a problem to be solved. In particular, in the case of a Through Silicon Via (TSV) bonding process for manufacturing a stack semiconductor device, a plurality of electrode pads may be arranged on front surfaces of the dies, and misalignment of the dies may occur during a die bonding process using the picker.

### SUMMARY

Aspects of the inventive concept provide a die bonding apparatus capable of precisely aligning a plurality of dies with one another.

According to an aspect of the inventive concept, there is provided a die bonding apparatus including a stage configured to support a first die, a pickup head configured to pick up a second die, regions of magnetic material arranged on the first die and the second die, an electromagnet arranged on a surface of each of the pickup head or the stage, and a controller configured to apply a current to the electromagnet to generate a magnetic field when the first die and the second die are disposed at a predetermined distance from each other in a vertical direction, wherein, because of the magnetic field generated by the electromagnet, the regions of magnetic material arranged on the first die and the second die are aligned with one another in a vertical direction.

According to another aspect of the inventive concept, there is provided a die bonding apparatus including a stage configured to support a first die, a stage driver configured to move the stage in a horizontal direction and a vertical direction perpendicular to the horizontal direction, a pickup head configured to pick up a second die, regions of magnetic material arranged on the first die and the second die, an electromagnet arranged on a surface of the pickup head or the stage, and, a controller configured to apply a current to the electromagnet to generate a magnetic field when the first die and the second die are disposed at a predetermined distance from each other in the vertical direction, wherein the pickup head further comprises a die adhesive surface that faces an upper surface of the second die, and wherein because of the magnetic field generated by the electromagnet, the regions of magnetic material arranged on the first die and the second die are aligned with one another in the vertical direction.

According to another aspect of the inventive concept, there is provided a die bonding apparatus including a stage configured a first die and a substrate, a stage driver configured to move the stage in a horizontal direction and a vertical direction perpendicular to the horizontal direction, a pickup head configured to pick up a second die, a pickup head driver configured to move the pickup head in the horizontal direction, regions of magnetic material arranged on the first die and the second die, an electromagnet arranged on a surface of each of the pickup head or the stage, and a controller configured to apply a current to the electromagnet to generate a magnetic field when the first die and the second die are disposed at a predetermined distance from each other in a vertical direction, wherein the pickup head further comprises a die adhesive surface that is opposite to an upper surface of the second die and spaced apart from the upper surface of the second die in the vertical direction, and wherein because of the magnetic field generated by the electromagnet, the regions of magnetic material arranged on the first die and the second die are aligned in the vertical direction.

### BRIEF DESCRIPTION OF THE DRAWINGS

Embodiments will be more clearly understood from the following detailed description taken in conjunction with the accompanying drawings in which:

FIG. 1 schematically shows a die bonding apparatus according to an embodiment;

FIG. 2 is a cross-sectional view of a bonding head of the die bonding apparatus of FIG. 1, according to an embodiment;

FIG. 3 is a plan view of a die including a plurality of magnetic materials, according to an embodiment;

FIG. 4 is a cross-sectional view showing that a plurality of dies are bonded in a vertical direction, according to an embodiment;

FIG. 5 schematically shows a die bonding apparatus according to an embodiment;

FIG. 6 schematically shows a die bonding apparatus according to an embodiment;

FIG. 7 is a flowchart of a die bonding method according to an embodiment; and

FIG. 8 is a cross-sectional view of a semiconductor device manufactured using a die bonding apparatus, according to an embodiment.

### DETAILED DESCRIPTION OF THE EMBODIMENTS

Hereinafter, embodiments of the inventive concept will be described below in detail with reference to the accompanying drawings. Like reference numerals in the drawings denote like elements, and repeated descriptions thereof will be omitted.

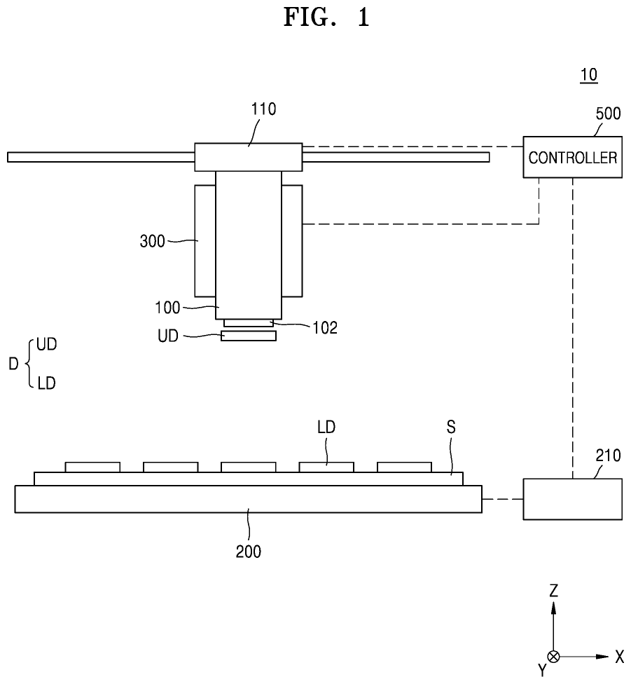

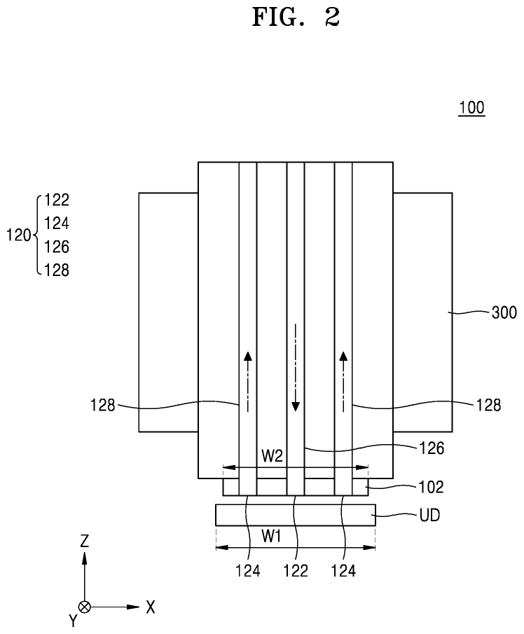

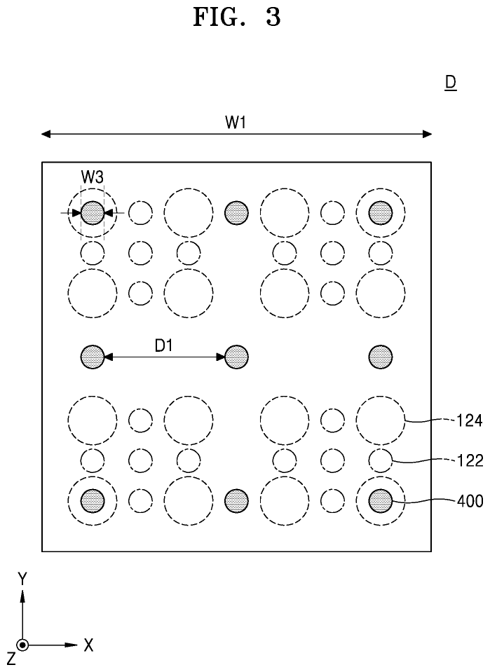

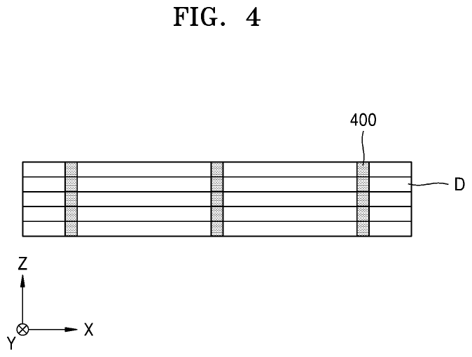

FIG. 1 schematically shows a die bonding apparatus according to an embodiment. FIG. 2 is a cross-sectional view of a bonding head of the die bonding apparatus of FIG. 1, according to an embodiment. FIG. 3 is a plan view of a die including a plurality of magnetic materials, according to an embodiment, and FIG. 4 is a cross-sectional view showing that a plurality of dies are bonded in a vertical direction, according to an embodiment. Arrows in FIG. 2 may indicate the flow of air. For convenience of illustration, FIG. 2 shows that a bonding head 100 includes one air injection nozzle 122, two vacuum holes 124, one air line 126, and two suction lines 128. However, the number of air injection nozzles 122, vacuum holes 124, air lines 126, and/or suction lines 128 included in the bonding head 100 are not limited thereto. In FIG. 3, solid lines in a die D may indicate regions of magnetic material 400, and dashed lines may indicate portions of a die adhesive surface 102 of the bonding head 100 which overlap the air injection nozzles 122 and the vacuum holes 124 in a vertical direction (a Z direction).

Referring to FIGS. 1 to 4, a die bonding apparatus 10 may include the bonding head 100, a stage 200, a magnet 300, and a controller 500. The die bonding apparatus 10 may pick up dies D individualized through a dicing process during the manufacture of a semiconductor device and bond the individualized dies D to a lead frame, a printed circuit board, a semiconductor wafer, and/or different dies D. The die bonding apparatus 10 may bond the dies D to a substrate S.

The bonding head 100 may move the dies D in a horizontal direction (an X direction and/or a Y direction) while picking up the same. For example, the bonding head 100 may pick up the dies D in a non-contact manner. That is, the bonding head 100 may be a non-contact picker (NCP). The bonding head 100 may pick up the dies D without physically contacting front, side and/or rear surfaces of the dies D. For example, as detailed below, the die adhesive surface 102 of the bonding head 100 may be spaced apart from upper surfaces of the dies D in the vertical direction (the Z direction) when the bonding head 100 picks up the dies in the non-contact manner.

In the specification, the horizontal direction (the X direction and/or the Y direction) may denote a direction parallel to a main surface of the stage 200, and the vertical direction (the Z direction) may denote a direction perpendicular to the horizontal direction (the X direction and/or the Y direction).

The bonding head 100 may include the die adhesive surface 102 facing the die D. For example, a horizontal area of the die adhesive surface 102 may be less than a horizontal area of the die D. When the horizontal area of the die adhesive surface 102 is less than the horizontal area of the die D, the die D may be relatively easily moved in the horizontal direction (the X direction and/or the Y direction). On the contrary, when the horizontal area of the die adhesive surface 102 is equal to or greater than the horizontal area of the die D, the movement of the die D in the horizontal direction (the X direction and/or the Y direction) may not be relatively easy.

A horizontal cross-section of each of the die adhesive surface 102 and the die D may have a substantially square shape. In another embodiment, the horizontal cross-section of each of the die adhesive surface 102 and the die D may have a substantially rectangular shape. A first width W1 that is a width of the die D in the horizontal direction (the X direction and/or the Y direction) may be between about 5 mm and about 15 mm. A second width W2 that is a width of the die adhesive surface 102 in the horizontal direction (the X direction and/or the Y direction) may be between about 2.5 mm and about 15 mm. A ratio of the second width W2 to the first width W1 may be equal to or greater than about 50% and less than or equal to about 100%.

The die bonding apparatus 10 may further include a bonding head driver 110 configured to move the bonding head 100 in the horizontal direction (the X direction and/or the Y direction). The bonding head 100 may include a flow path 120.

The flow path 120 may supply an airflow space in the bonding head 100. The flow path 120 may be configured such that the bonding head 100 picks up the die D in a non-contact manner. The flow path 120 may include one or more air injection nozzles 122 configured to form an airflow, a plurality of vacuum holes 124 configured to suck in the air sprayed from the air injection nozzles 122, an air line 126 through which the air is supplied to the air injection nozzles 122, and a suction line 128 through which the air sucked in the vacuum holes 124 moves. The air injection nozzles 122 and the air line 126 may spray the air that pushes the dies in the vertical direction, and the vacuum holes 124 and the suction line 128 may be configured such that the bonding head 100 may have a suction force to the dies D. For example, the vacuum holes 124 may be arranged adjacent to the air injection nozzles 122. The air line 126 and the suction line 128 may extend by penetrating the bonding head 100 in the substantially vertical direction (the Z direction). The air line 126 may be connected to an air tank (not shown) configured to supply the air. When the force pushing the die D and the force attracting the die D are parallel, the bonding head 100 may pick up the die D without contacting the die. D When the bonding head 100 picks up the die D in a non-contact manner, a thin film of air may be present between the die D and the die adhesive surface 102. Controller 500 may generate and maintain the thin film of air by adjusting the airflow from the one or more air injection nozzles 122 and the vacuum holes 124.

The die D and the die adhesive surface 102 may be divided into multiple corresponding regions. For example, the die adhesive surface 102 may be divided into multiple regions in which the air injection nozzles 122 and the vacuum holes 124 are arranged adjacent to each other and form pairs. Accordingly, positive and negative airflow on respective regions of the die D may be independently controlled by controlling, via the controller 500, the air supplied to the air injection nozzle 122 or a flow rate of air sucked into the vacuum holes 124 in each region. For example, the air line 126 and the suction line 128 arranged in each region may be independently controlled such that a die D may be picked up and held in vertical proximity to the die adhesive surface 102 such that a thin film of air is present between the adhesive surface 102 and the die D. The thin film of air present between the adhesive surface 102 and the die D prevents physical contact between the die D and the bonding head 100. Accordingly, the bonding head 100 may pick up the dies D in a non-contact manner. Moreover, as the bonding 100 picks up the dies D in a non-contact manner, a degree of movement of the die in the horizontal direction (the X direction and/or the Y direction) is possible when a magnetic field is applied within the die bonding apparatus 10 as discussed in further detail below.

For example, the air injection nozzles 122 and the vacuum holes 124 may be arranged on the die adhesive surface 102. For example, a diameter of the air injection nozzle 122 may be less than that of the vacuum hole 124.

FIG. 3 shows an example in which the die D is divided into four regions and controlled, but one or more embodiments are not limited thereto. The die adhesive surface 102 may be divided into four corresponding regions. Also, some of the vacuum holes 124 are aligned with the regions of magnetic material 400 in the vertical direction (the Z direction), but one or more embodiments are not limited thereto.

The stage 200 may further include a stage driver 210 configured to move the stage 200 in the horizontal direction (the X direction and/or the Y direction) and the vertical direction (the Z direction). The stage 200 may be moved by the stage driver 210, and thus, the die D picked up by the bonding head 100 may come close to the die D on the substrate S.

The stage 200 may support the substrate S. The substrate S may be, for example, a wafer. The dies D may be arranged on the substrate S. For example, the stage 200 may support the dies D. In another embodiment, a semiconductor device, in which the dies D are stacked on the substrate S in the vertical direction (the Z direction), may be included.

The die bonding apparatus 10 may bond the die D disposed on the stage 200 to the die D picked up by the bonding head 100. The die bonding apparatus 10 may bond the die D picked up by the bonding head 100 to the die D disposed on the stage 200. Here, the die D on the stage 200 may be a lower die LD, and the die D picked up by the bonding head 100 may be an upper die UD.

The bonding head 100 may pick up the upper die UD in a non-contact manner, and the upper die UD may be relatively easily moved in the horizontal direction (the X direction and/or the Y direction). On the contrary, when the bonding head 100 picks up the upper die UD in a contact manner, the upper die UD may not be relatively easily moved in the horizontal direction (the X direction and/or the Y direction).

The magnet 300 may generate a magnetic field. For example, the magnet 300 may be arranged on a side surface of the bonding head 100. For example, the magnet 300 may be an electromagnet. The magnet 300 may be selectively turned on/off. For example, the magnet 300 may include a solenoid coil. For example, when a current is applied to the magnet 300, the magnet 300 may be on duty. For example, when a current is not applied to the magnet 300, the magnet 300 may be off duty. The magnet 300 may generate a magnetic field in the vertical direction (the Z direction). For example, the magnet 300 may generate a magnetic field of about 2000 Gauss or greater.

The regions of magnetic material 400 may be arranged in the die D. For example, the regions of magnetic material 400 are comprised of a magnetic material, which may include a soft magnetic material. When the regions of magnetic material 400 includes a soft magnetic material, the regions of magnetic material 400 may have high permeability and high saturation magnetization. Therefore, an attraction force of the regions of magnetic material 400 by a magnetic force may be maximized. For example, the regions of magnetic material 400 may include NiFe, FeCo, FeCoB, and/or an alloy thereof. For example, the regions of magnetic material 400 may include Ni₈₀Fe₂₀.

For example, one die D may include multiple regions of magnetic material 400. The regions of magnetic material 400 may be arranged in a dummy pad, an alignment key, and/or a scribe lane of the die D. For example, a horizontal cross-section of each region of magnetic material 400 may have a rectangular, circular, and/or polygonal shape. For example, a third width W3 that is a horizontal diameter of each region of magnetic material 400 may be less than or equal to about 2 micrometers. Also, a first distance D1 that is a horizontal distance between adjacent regions of magnetic material 400 may be less than or equal to about 4 micrometers.

The regions of magnetic material 400 arranged on different dies D may be aligned with one another in the vertical direction (the Z direction) because of the magnetic field generated in the magnet 300. That is, the dies D spaced apart in the vertical direction (the Z direction) may be aligned with one another in the vertical direction (the Z direction) because of the magnetic field generated in the magnet 300. That is, the dies D spaced apart in the vertical direction (the Z direction) may be overlapped with one another. An error distance that is an error in the alignment of the dies D, which are spaced apart from each other in the vertical direction (the Z direction), in the horizontal direction (the X direction and/or Y direction) may be less than or equal to about 50 nanometers. For example, the error distance may be less than or equal to about 20 nanometers. For example, the error distance may be less than or equal to about 1% of the third width W3. The error distance compared to the third width W3 may be an error rate. The error rate may still be less than or equal to about 1% even when the third width W3 increases.

The controller 500 may be connected to the bonding head driver 110, the stage driver 210, and the magnet 300. The controller 500 may control the bonding head driver 110 to make the bonding head 100 pick up the dies D in a non-contact manner and to move the bonding head 100. Also, the controller 500 may move the stage 200 by controlling the stage driver 210. As described below, the controller 500 may move the stage 200 and, therefore, move the lower die LD to be adjacent to the upper die UD. As used herein, the term “macroscopic alignment” or “first alignment” may refer to the controller 500 aligning the upper die UD and the lower die LD in the vertical direction (the Z direction) through the movement of the bonding head driver 110 and/or the stage 200. Subsequently, the controller 500 may apply a current to the magnet 300 to further align the lower die LD with the upper die UD in the vertical direction (the Z direction). As used herein, the term “microscopic alignment” or “second alignment” may refer to the controller 500 aligning the upper die UD and the lower die LD in the vertical direction (the Z direction) through the application of a current to the magnet 300.

The controller 500 may be realized as hardware, firmware, software, or a combination thereof. For example, the controller 500 may be a computing device of a workstation computer, a desktop computer, a laptop, a tablet computer, or the like. For example, the controller 500 may include a memory device, such as Read Only Memory (ROM) or Random Access Memory (RAM), a processor, for example, a microprocessor, a Central Processing Unit (CPU), a Graphics Processing Unit (GPU), or the like, which is configured to perform a certain arithmetic operation and an algorithm. Also, the controller 500 may include a receiver and a transmitter for receiving and transmitting electrical signals.

A general die bonding apparatus may pick up dies in a contact manner, and thus, the dies picked up by a bonding head may not be relatively easily moved in a horizontal direction. Also, in the general die bonding apparatus, because a horizontal area of a die adhesive surface of the bonding head is greater than or equal to about a horizontal area of the die, the horizontal movement of the dies picked up by the bonding head is not relatively easy. Therefore, in a general die bonding apparatus, when the dies are bonded in a vertical direction, an alignment error may be relatively large.

However, the die bonding apparatus 10 according to aspects of the inventive concept picks up the dies in a non-contact manner, and thus, the upper die UD picked up by the bonding head 100 may be relatively easily moved in the horizontal direction (the X direction and/or the Y direction). For example, because there is no physical contact between the upper die UD picked up by the bonding head 100 and the bonding head 100 (e.g., the die adhesive surface 102), the upper die UD may be relatively easily moved in the horizontal direction (the X direction and/or the Y direction). Also, in the die bonding apparatus 10 according to aspects of the inventive concept, because the horizontal area of the die adhesive surface 102 of the bonding head 100 is less than the horizontal area of the die D, the die D picked up by the bonding head 100 may be relatively easily moved in the horizontal direction (the X direction and/or the Y direction). Therefore, when the dies D are bonded in the vertical direction (the Z direction), the alignment error may be relatively small. Therefore, the reliability and stability of a semiconductor device manufactured using the die bonding apparatus 10 may be improved.

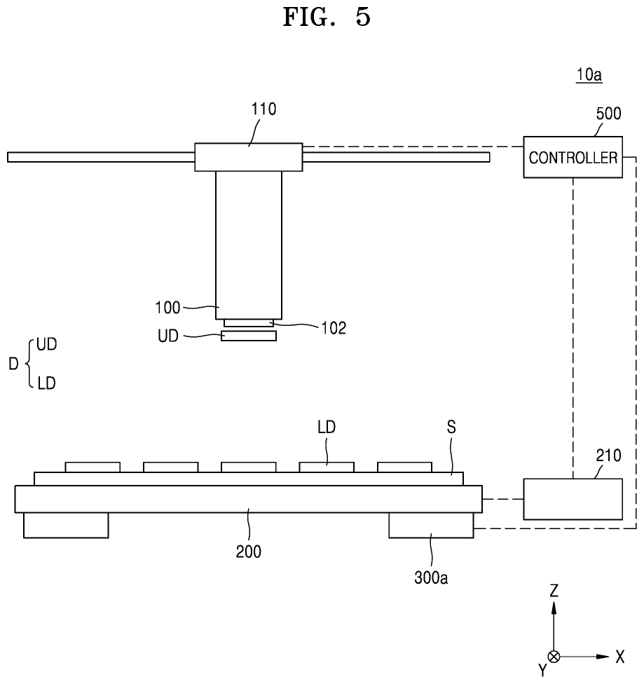

FIG. 5 schematically shows a die bonding apparatus according to an embodiment. A die bonding apparatus 10a of FIG. 5 may include the bonding head 100, the stage 200, a magnet 300a, and the controller 500. The bonding head 100, the stage 200, and the controller 500 of the die bonding apparatus 10a of FIG. 5 are substantially the same as the bonding head 100, the stage 200, and the controller 500 of the die bonding apparatus 10 of FIG. 1, and thus, the magnet 300a is only described hereinafter.

Referring to FIG. 5, the magnet 300a may be arranged under the stage 200. For example, the magnet 300a may be an electromagnet. The magnet 300a may be selectively turned on/off. For example, the magnet 300a may include a solenoid coil. The magnet 300a may generate a magnetic field in the vertical direction (the Z direction). For example, the magnet 300a may generate a magnetic field of about 2000 Gauss or greater.

Because of the magnetic field generated by the magnet 300a, the regions of magnetic material 400 of the lower die LD on the stage 200 may be vertically aligned with the regions of magnetic material 400 of the upper die UD picked up by the bonding head 100. Therefore, the dies D spaced apart in the vertical direction (the Z direction) may be aligned with one another in the in the vertical direction (the Z direction) because of the magnetic field generated by the magnet 300a.

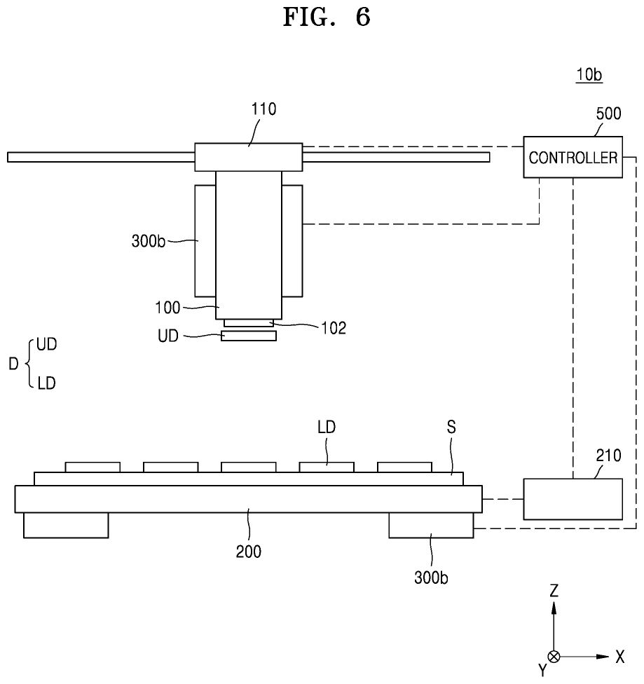

FIG. 6 schematically shows a die bonding apparatus according to an embodiment. A die bonding apparatus 10b of FIG. 6 may include the bonding head 100, the stage 200, magnets 300b, and the controller 500. The bonding head 100, the stage 200, and the controller 500 of the die bonding apparatus 10b of FIG. 6 are substantially the same as the bonding head 100, the stage 200, and the controller 500 of the die bonding apparatus 10 of FIG. 1, and thus, the magnets 300b are only described hereinafter.

Referring to FIG. 6, the magnets 300b may be arranged on a side surface of the bonding head 100 and under the stage 200, respectively. For example, the magnets 300b may each be an electromagnet. The magnets 300b may be selectively turned on/off. For example, according to convenience, at least one of the magnets 300b may be selectively turned on/off.

For example, the magnets 300b may include solenoid coils. The magnets 300b may generate a magnetic field in the vertical direction (the Z direction). For example, the magnets 300b may generate a magnetic field of about 2000 Gauss or greater.

Because of the magnetic field generated by each magnet 300b, the regions of magnetic material 400 of the lower die LD on the stage 200 may be vertically aligned with the regions of magnetic material 400 of the upper die UD picked up by the bonding head 100. Therefore, the dies D spaced apart in the vertical direction (the Z direction) may be aligned with one another in the in the vertical direction (the Z direction) because of the magnetic fields generated by the magnets 300b.

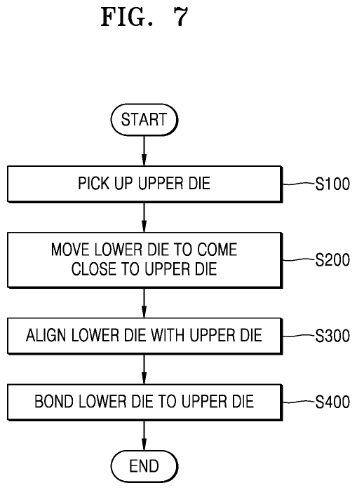

FIG. 7 is a flowchart of a die bonding method according to an embodiment.

Referring to FIGS. 1 to 4 and 7, the bonding head 100 may pick up the upper die UD, in operation S100. As described above, the bonding head 100 may pick up the dies D in a non-contact manner. As described above, the dies D picked up by the bonding head 100 may be referred to as the upper dies UD. In this case, a horizontal area of the die adhesive surface 102 of the bonding head 100 may be less than a horizontal area of the die D.

Then, in operation S200, the controller 500 may move the stage 200 and/or bonding head 100, and thus, the die D on the stage 200 may come close to the upper die UD. As described above, the die D on the stage 200 may be referred to as a lower die LD. For example, the controller 500 may move the stage 200 and/or bonding head 100 in the horizontal direction (the X direction and/or the Y direction) such that the lower die LD may be aligned with the upper die UD in the in the vertical direction (the Z direction) such that the error distance may be less than or equal to about 100 micrometers (i.e., “macroscopic alignment” or “first alignment”). The controller 500 may further move the stage 200 and/or bonding head 100 in the vertical direction (the Z direction) such that the upper die UD may be moved to be close to the lower die LD in the vertical direction (the Z direction). For example, the controller 500 may further move the stage 200 and/or bonding head 100 in the vertical direction (the Z direction) such that the distance between the upper die UD and the lower die LD may be less than or equal to about 100 micrometers FIGS. 1, 5, and 6 show an example in which respective dies D are arranged on the stage 200, but for example, the dies D may be bonded to the stage 200 in the vertical direction (the Z direction). The die bonding apparatus 10 may include a vision camera (not shown), which may be used to assist in the movement and alignment of the lower die LD and the upper die UD by determining and/or confirming a position of the lower die LD and the upper die UD in the horizontal direction (the X direction and/or the Y direction) and/or the vertical direction (the Z direction).

In operation S300, subsequent to the controller moving the stage 200 and/or bonding head 100 to align the upper die UD and the lower die LD in the vertical direction (the Z direction) such that the error distance is less than or equal to about 100 micrometers and disposing the upper die UD and the lower die LD in close proximity (e.g., less than or equal to about 100 micrometers) in the vertical direction (the Z direction), the controller 500 may apply a current to the magnet 300 to further align the lower die LD and the upper die UD with respect to each other in the vertical direction (the Z direction) (i.e., “microscopic alignment” or “second alignment”). When the current is applied to the magnet 300, a magnetic field may be generated in the vertical direction (the Z direction). For example, the magnet 300 may generate a magnetic field of about 2000 Gauss or greater. Because of the magnetic field, the regions of magnetic material 400 of the lower die LD may be aligned with the regions of magnetic material 400 of the upper die UD in the vertical direction (the Z direction). Because the bonding head 100 picks up the upper die UD in a non-contact manner, the upper die UD may be easily moved in the horizontal direction (the X direction and/or the Y direction). Subsequent to operation S300, the error distance may be less than or equal to about 20 nanometers. For example, subsequent to operation S300, the error distance may be less than or equal to about 1% of the third width W3. The error distance compared to the third width W3 may be an error rate. The error rate may still be less than or equal to about 1% even when the third width W3 increases.

That is, the dies D spaced apart in the vertical direction (the Z direction) may be aligned with a reduced (i.e., minimal) error distance in the horizontal direction (the X direction and/or Y direction) because of the magnetic field generated by the magnet 300. For example, the lower die LD may be aligned with the upper die UD in the vertical direction (the Z direction) with an error distance less than or equal to about 20 nanometers.

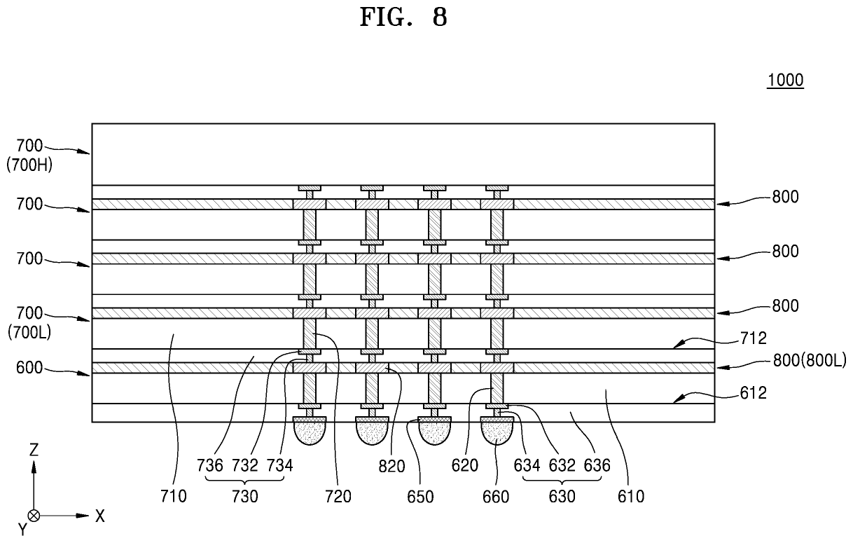

Then, the lower die LD may be bonded to the upper die UD. As the dies D are bonded, a semiconductor device (1000 of FIG. 8) may be manufactured.

FIG. 8 is a cross-sectional view of a semiconductor device manufactured using a die bonding apparatus, according to an embodiment.

Referring to FIGS. 1, 4, and 8, the die bonding apparatus 10 may be used to manufacture the semiconductor device 1000 as the dies D are stacked in the vertical direction (the Z direction).

The semiconductor device 1000 may include a first semiconductor chip 600 and second semiconductor chips 700. FIG. 8 shows that the semiconductor device 1000 includes four second semiconductor chips 700, but one or more embodiments are not limited thereto. For example, the semiconductor device 1000 may include two or more semiconductor chips 700. In some embodiments, the semiconductor device 1000 may include multiples of four second semiconductor chips 700. The second semiconductor chips 700 may be sequentially stacked on the first semiconductor chip 600. For convenience of explanation, the second semiconductor chip 700, which is the lowermost one of the second semiconductor chips 700, may be referred to as a lowermost second semiconductor chip 700L, and the second semiconductor chip 700, which is the uppermost one of the second semiconductor chips 700, may be referred to as an uppermost second semiconductor chip 700H.

The first semiconductor chip 600 of the semiconductor device 1000 may be electrically connected to the second semiconductor chips 700 thereof through connection pads 820, and thus, signals may be exchanged between the first semiconductor chip 600 and the second semiconductor chips 700, and power and ground may be provided to the first semiconductor chip 600 and the second semiconductor chips 700. For example, the connection pads 820 may be respectively arranged between the first semiconductor chip 600 and the lowermost second semiconductor chip 700L and between each two adjacent second semiconductor chips 700.

For example, the connection pads 820 may include a material containing copper (Cu). The connection pads 820, which are arranged between the first semiconductor chip 600 and the lowermost second semiconductor chip 700L among the connection pads 820, may be referred to as first connection pads, and the connection pads 820, which are arranged between each two adjacent second semiconductor chips 700, may be referred to as second connection pads.

The first semiconductor chip 600 may include a first semiconductor substrate 610 having an active surface and an inactive surface that are opposite to each other, a first semiconductor device 612 formed on the active surface of the first semiconductor substrate 610, a first wiring structure 630 formed on the active surface of the first semiconductor substrate 610, and a plurality of first through electrodes 620 connected to the first wiring structure 630 and penetrating at least a portion of the first semiconductor chip 600. The first semiconductor chip 600 may further include a plurality of chip pads 650 that are arranged in a lower surface of the first semiconductor chip 600 and electrically connected to a first wiring pattern 632 and/or a first wiring via 634. The chip pads 650 may be electrically connected to the first semiconductor device 612 or the first wiring structure 630 through the first wiring pattern 632 and/or the first wiring via 634. A plurality of connection terminals 660 may be arranged on lower surfaces of the chip pads 650, respectively. The connection terminals 660 may include, for example, solder balls. In some embodiments, the semiconductor device 1000 may not include the connection terminals 660.

In the semiconductor device 1000, the first semiconductor chip 600 may be arranged to make the active surface of the first semiconductor substrate 610 face downwards and the inactive surface of the first semiconductor substrate 610 face upwards. Therefore, unless otherwise separately stated, the upper surface of the first semiconductor chip 600 of the semiconductor device 1000 may be a side that faces the inactive surface of the first semiconductor substrate 610, and the lower surface of the first semiconductor chip 600 may be a side that faces the active surface of the first semiconductor substrate 610. When the description is provided based on the first semiconductor chip 600, the lower surface of the first semiconductor chip 600, which faces the active surface of the first semiconductor substrate 610, may be referred to as a front surface of the first semiconductor chip 600, and the upper surface of the first semiconductor chip 600, which faces the inactive surface of the first semiconductor substrate 610, may be referred to as a rear surface of the first semiconductor chip 600.

The second semiconductor chip 700 includes a second semiconductor substrate 710 having an active surface and an inactive surface that are opposite to each other, a second semiconductor device 712 formed on the active surface of the second semiconductor substrate 710, and a second wiring structure 730 formed on the active surface of the second semiconductor substrate 710.

At least some of the second semiconductor chips 700 may further include a plurality of second through electrodes 720 that are connected to the second wiring structure 730 and penetrate at least a portion of the second semiconductor chip 700. In some embodiments, the uppermost second semiconductor chip 700H, which is the farthest from the first semiconductor chip 600 and arranged on an uppermost portion of the semiconductor device 1000 among the second semiconductor chips 700, may not include the second through electrodes 720.

On an upper surface of the uppermost second semiconductor chip 700H, the second semiconductor substrate 710 may only be exposed. That is, a semiconductor material may only be arranged on the upper surface of the uppermost second semiconductor chip 700H. A thickness of the uppermost second semiconductor chip 700H in the vertical direction (the Z direction) may be greater than the thicknesses of the other second semiconductor chips 700, except for the first semiconductor chip 600 in the vertical direction (the Z direction).

In the semiconductor device 1000, the second semiconductor chips 700 may be sequentially stacked on the first semiconductor chip 600 in the vertical direction (the Z direction) while the active surface of the second semiconductor substrate 710 faces downwards, that is, faces the first semiconductor chip 600. Therefore, unless otherwise stated separately, the upper surface of the second semiconductor chip 700 of the semiconductor device 1000 may be a side that faces the inactive surface of the second semiconductor substrate 710, and the lower surface of the second semiconductor chip 700 may be a side that faces the active surface of the second semiconductor substrate 710. When the description is provided based on the semiconductor chip 700, the lower surface of the second semiconductor chip 700, which faces the active surface of the second semiconductor substrate 710, may be referred to as a front surface of the second semiconductor chip 700, and the upper surface of the second semiconductor chip 700, which faces the inactive surface of the second semiconductor substrate 710, may be referred to as a rear surface of the second semiconductor chip 700.

The first semiconductor substrate 610 and the second semiconductor substrate 710 may each include, for example, a semiconductor material, such as silicon (Si). Alternatively, the first semiconductor substrate 610 and the second semiconductor substrate 710 may each include, for example, a semiconductor material, such as germanium (Ge). Each of the first semiconductor substrate 610 and the second semiconductor substrate 710 may have an active surface and an inactive surface that is opposite to the active surface. The first semiconductor substrate 610 and the second semiconductor substrate 710 may each include a conductive area, for example, a well doped with impurities. The first semiconductor substrate 610 and the second semiconductor substrate 710 may each have a device isolation structure, such as a shallow trench isolation (STI) structure.

Each of the first semiconductor substrate 610 and the second semiconductor substrate 710 may include individual devices of various types. Each individual device may be electrically connected to the conductive area of the first semiconductor substrate 610 or the second semiconductor substrate 710. Each of the first semiconductor substrate 610 and the second semiconductor substrate 710 may further include a conductive line or a conductive plug that electrically connects at least two of the individual devices or the individual devices to the conductive area of each of the first semiconductor substrate 610 and the second semiconductor substrate 710. Also, the individual devices may be electrically separated from other neighboring individual devices by insulating layers, respectively.

At least one of the first semiconductor chip 600 and the second semiconductor chip 700 may be a memory semiconductor chip. In some embodiments, the first semiconductor chip 600 may be a buffer chip including a serial-parallel conversion circuit and used to control the second semiconductor chips 700, and the second semiconductor chips 700 may each be a memory chip including memory cells. For example, the semiconductor device 1000 including the first semiconductor chip 600 and the second semiconductor chips 700 may be High Bandwidth Memory (HBM), the first semiconductor chip 600 may be referred to as an HBM controller die, and the second semiconductor chips 700 may each be referred to as a DRAM die.

The first wiring structure 630 may include a plurality of first wiring patterns 632, a plurality of first wiring vias 634 connected to the first wiring patterns 632, and a first inter-wiring insulating layer 636 covering the first wiring patterns 632 and the first wiring vias 634. In some embodiments, the first wiring structure 630 may have a multilayered wiring structure in which the first wiring patterns 632 and the first wiring vias 634 are arranged at different vertical levels.

A second wiring structure 730 may include a plurality of second wiring patterns 732, a plurality of second wiring vias 734 connected to the second wiring patterns 732, and a second inter-wiring insulating layer 736 covering the second wiring patterns 732 and the second wiring vias 734. In some embodiments, the second wiring structure 730 may have a multilayered wiring structure in which the second wiring patterns 732 and the second wiring vias 734 are arranged at different vertical levels.

The first wiring patterns 632, the first wiring vias 634, the chip pads 650, the second wiring patterns 732, and the second wiring vias 734 may each include, for example, metallic materials, such as aluminum (Al), Cu, or tungsten (W). In some embodiments, the first wiring patterns 632, the first wiring vias 634, the chip pads 650, the second wiring patterns 732, and the second wiring vias 734 may each include a wiring barrier layer and a wiring metal layer. The wiring barrier layer may include metal, metal nitride, or an alloy. The wiring metal layer may include at least one metal selected from among W, Al, titanium (TI), tantalum (Ta), ruthenium (Ru), manganese (Mn), and Cu.

Each of the first through electrode 620 and the second through electrode 720 may be a Through Silicon Via (TSV).

The connection pads 820 may electrically connect the second wiring patterns 732 and/or the second wiring vias 734 of the second wiring structure 730 to the first through electrodes 620 and/or the second through electrodes 720 arranged on the lower portion of the semiconductor device 1000.

For example, the second wiring patterns 732 and/or the second wiring vias 734 of the second wiring structure 730 of the lowermost second semiconductor chip 700L may be electrically connected to the first through electrodes 620 of the first semiconductor chip 600, which is arranged on the lower portion of the semiconductor device 1000, through the first connection pads. The second connection pads, and the second wiring patterns 732 and/or the second wiring vias 734 of the second wiring structure 730 of the second semiconductor chips 700 may be electrically connected to the second through electrodes 720 of the second semiconductor chips 700.

The connection pads 820 may be respectively surrounded by chip connection insulating layers 800 between the first semiconductor chip 600 and the second semiconductor chips 700, that is, between the first semiconductor chip 600 and the lowermost second semiconductor chip 700L, and between the second semiconductor chips 700. The connection pads 820 may penetrate the chip connection insulating layers 800. The chip connection insulating layers 800 may be arranged between the first semiconductor chip 600 and the second semiconductor chips 700, respectively.

FIG. 8 exemplarily shows that the semiconductor device 1000 according to aspects of the inventive concept is part of a 2.5 dimensional stack structure, but one or more embodiments are not limited thereto. For example, the semiconductor device 1000 may be part of a lower semiconductor package or an upper semiconductor package forming a semiconductor device 1000 of a Package on Package (PoP) type. The semiconductor device 1000 may be part of a three-dimensional semiconductor package. For example, the semiconductor device 1000 may include a plurality of semiconductor packages, and the semiconductor device 1000 may be part of a System-In-Package (SIP) in which semiconductor chips of different types are electrically interconnected to each other and which operates as one system.

While aspects of the inventive concept have been particularly shown and described with reference to embodiments thereof, it will be understood that various changes in form and details may be made therein without departing from the spirit and scope of the following claims.

What is claimed is:

1. A die bonding apparatus comprising:
a stage configured to support a first die;
a pickup head configured to pick up a second die;
regions of magnetic material arranged on the first die and the second die;
an electromagnet arranged on a surface of the pickup head or the stage; and
a controller configured to apply a current to the electromagnet to generate a magnetic field when the first die and the second die are disposed at a predetermined distance from each other in a vertical direction,
wherein, because of the magnetic field generated by the electromagnet, the regions of magnetic material arranged on the first die and the second die are aligned with one another in the vertical direction.

2. The die bonding apparatus of claim 1, wherein the pickup head is configured to pick up the second die in a non-contact manner.

3. The die bonding apparatus of claim 1, further comprising a stage driver configured to move the stage in the vertical direction or a horizontal direction perpendicular to the vertical direction.

4. The die bonding apparatus of claim 1, wherein the electromagnet comprises a solenoid coil.

5. The die bonding apparatus of claim 1, wherein the electromagnet generates a magnetic field in the vertical direction.

6. The die bonding apparatus of claim 1, wherein the pickup head further comprises a die adhesive surface facing an upper surface of the second die, and
a horizontal area of the die adhesive surface is less than a horizontal area of the second die.

7. The die bonding apparatus of claim 1, wherein the regions of magnetic material include soft magnetic materials.

8. A die bonding apparatus comprising:
a stage configured to support a first die;
a stage driver configured to move the stage in a horizontal direction and a vertical direction perpendicular to the horizontal direction;
a pickup head configured to pick up a second die;
regions of magnetic material arranged on the first die and the second die;
an electromagnet arranged on a surface of the pickup head or the stage; and,
a controller configured to apply a current to the electromagnet to generate a magnetic field when the first die and the second die are disposed at a predetermined distance from each other in the vertical direction,
wherein the pickup head further comprises a die adhesive surface that faces an upper surface of the second die, and
wherein because of the magnetic field generated by the electromagnet, the regions of magnetic material arranged on the first die and the second die are aligned with one another in the vertical direction.

9. The die bonding apparatus of claim 8, wherein a lower surface of the die adhesive surface of the pickup head is spaced apart from an upper surface of the second die in the vertical direction.

10. The die bonding apparatus of claim 8, further comprising an air line configured to supply air to the second die and a suction line configured to suck in the air, wherein the air line and the suction line are formed in the pickup head.

11. The die bonding apparatus of claim 10, further comprising one or more air injection nozzles connected to the air line and one or more vacuum holes connected to the suction line, wherein the one or more air injection nozzles and the one or more vacuum holes are arranged on the die adhesive surface.

12. The die bonding apparatus of claim 11, wherein a flow rate of air provided to each of the one or more air injection nozzles or a flow rate of air sucked into each of the one or more vacuum holes is independently controlled.

13. The die bonding apparatus of claim 8, wherein a range of a ratio of a second width, which is a horizontal width of the die adhesive surface, to a first width, which is a horizontal width of the second die, is greater than or equal to about 50% and less than or equal to about 100%.

14. The die bonding apparatus of claim 8, wherein the electromagnet generates a magnetic field of at least about 2000 Gauss in the vertical direction.

15. The die bonding apparatus of claim 8, wherein the regions of magnetic material are arranged on at least one of a dummy pad, an alignment key, and a scribe lane of each of the first die and the second die.

16. A die bonding apparatus comprising:
a stage configured a first die and a substrate;
a stage driver configured to move the stage in a horizontal direction and a vertical direction perpendicular to the horizontal direction;
a pickup head configured to pick up a second die;
a pickup head driver configured to move the pickup head in the horizontal direction;
regions of magnetic material arranged on the first die and the second die;
an electromagnet arranged on a surface of each of the pickup head or the stage; and
a controller configured to apply a current to the electromagnet to generate a magnetic field when the first die and the second die are disposed at a predetermined distance from each other in a vertical direction,
wherein the pickup head further comprises a die adhesive surface that is opposite to an upper surface of the second die and spaced apart from the upper surface of the second die in the vertical direction, and
wherein because of the magnetic field generated by the electromagnet, the regions of magnetic material arranged on the first die and the second die are aligned in the vertical direction.

17. The die bonding apparatus of claim 16, wherein the controller applies the current to the electromagnet when a distance between the second die and the first die is less than or equal to about 100 micrometers.

18. The die bonding apparatus of claim 16, wherein the first die and the second die, which are aligned with one another in the vertical direction, have an error distance that is less than or equal to about 50 nanometers.

19. The die bonding apparatus of claim 16, wherein widths of the regions of magnetic material are less than or equal to about 2 micrometers.

20. The die bonding apparatus of claim 16, wherein the regions of magnetic material include soft magnetic materials and at least one of NiFe, FeCo, and FeCoB.
